(19) United States
(12) Patent Application Publication
(10) Pub. No.: US 2006/0106554 A1
(43) Pub. Date: May 18, 2006

(54) Current sensing lug

(75) Inventors: Timothy J. Borkowski, Houston, TX (US); Richard L. Grasshoff, Richmond, TX (US); R. Kenneth Murphy, Sugar Land, TX (US); Donato Cortez, Sugar Land, TX (US)

Correspondence Address: ALBERT B. KIMBALL, JR.;BRACEWELL & PATTERSON L L P, 711 LOUISANA SUITE 2900, HOUSTON, TX, 77002, US

(73) Assignee: CenterPoint Energy, Inc., Houston, TX (US)

(21) Appl. No.: 11/262,703

(22) Filed: Oct. 31, 2005

Related U.S. Application Data
(60) Provisional application No. 60/624,023, filed on Nov. 1, 2004.

(51) Int. Cl. G01R 19/00; G06F 19/00

(52) U.S. Cl. 702/64; 340/870.02

(57) ABSTRACT

Electrical current in an electrical power distribution system, such as at a power distribution transformer or the like, for an electrical utility is transferred through a current sensing connector lug mounted with an end of a user or consumer's service connection conductor or line. The lug is connectable to the power distribution transformer or secondary conductor, for connecting the user's service conductor to power from the distribution system. The flow of electrical current and thus the amount of electric power provided to an individual user is measured at the current sensing lug rather than at the user's site or facility, removing the need for watt-hour meters at the user or customer site, and also thus removing the requirement for conventional meter reading crews or for automated meter reading equipment. The current sensing lug also facilitates the accumulation of other utility data information, which formerly required a site visit by utility personnel.

### REFERENCE TO RELATED APPLICATIONS

This application claims the benefit of U.S. Provisional Patent Application Ser. No. 60/624,023, filed Nov. 1, 2004.

### BACKGROUND OF THE INVENTION

1. Field of the Invention

The present invention relates to sensing the amount of current flow in connection with metering or measuring of electrical energy usage for collection and communication of electrical energy usage data.

2. Description of the Related Art

So far as is known, the most common method for determining the amount of electricity delivered to a consumer has been to read an electric utility meter (usually measuring kilowatt hours), which was mounted on the home or building of the consumer being served. This arrangement was also usually comparable for both gas and water meters as well, with separate usage meters for each of the commodities provided by those utilities being located on or near the building or property being served. Service charges for those commodities were based on the amounts used, as indicated by the various meters. Because the various utility meters were located at a point where the utility commodity was delivered to the consumer, it became necessary for utility companies to establish routes composed of a number of user locations. A “meter reader” then periodically visited each meter for a utility on a particular route to record the amount of utility product consumed. The consumer was then periodically billed according to measured utility usage.

At present, many utility companies (including gas, electric, and water) have continued to send meter readers to consumer residences or buildings to collect utility meter readings. However, there are practical limitations on how efficiently this procedure can actually be performed. Personnel and staffing costs of meter reading crews became a concern as the numbers of users increased. Also, since security is a major concern of most homeowners today, access to the actual location of the consumer's meters has heightened security issues with consumer and utilities. Some consideration has thus been given to requesting that consumers themselves read their usage meters and periodically report usage readings for billing purposes. This, however, gives rise to other concerns. For instance, most consumers have little or no knowledge on how to read their meters, or how to gain access to meters themselves. This directly and adversely impacted the accuracy and efficiency of the self-reporting process.

The typical process of collecting meter data in the manner now in use thus had numerous disadvantages and inefficiencies. Collection of meter data was a labor intensive and costly process. Widespread use was made of electromechanical metering devices which were less expensive than electronic meters. However, electromechanical metering devices generally had little or no communication capability.

There was some thought and effort towards conversion to an automated meter reading (or AMR) system to overcome some of the problems discussed above. However, for AMR applications, electric utilities were still dependent on a meter device coupled with the service entrance on a home, apartment or business. The coupling arrangement for AMR applications typically made the utility meters electronically accessible, either to a meter reading device or by land line connections. However, the various individual meters still had to be read individually for automated meter reading or AMR. Thus, in AMR applications, an additional meter reading/communication device, such as a telemetry device in the form of a meter interface unit or telemetry interface unit was required. The meter reading/telemetry device had to serve as an interface between the two different environments: one being of the meter and one for the receipt and processing of usage data, and subsequent billing. This process has still not been widely used by most utilities because it is cost prohibitive in its adaptation and had mainly a limited, one-way communication, that of reporting usage read from a meter to some data processing center or site for processing and billing.

### SUMMARY OF THE INVENTION

Briefly, the present invention provides a new and improved current sensing lug to connect electrical power service from a power distribution system to a customer site and measure energy usage by the customer site. The current sensing lug according to the present invention has a connector terminal which is adapted to be connected to the power distribution system and a connector barrel adapted to be connected by a service conductor to the customer site. A lug body mounted between the connector terminal and the conductor barrel permits the flow of electrical power to the service conductor. An electrical current sensor of the lug obtains data indicating the amount of energy provided from the connector terminal to the service conductor.

### BRIEF DESCRIPTION OF THE DRAWINGS

A better understanding of the present invention can be obtained when the detailed description set forth below is reviewed in conjunction with the accompanying drawings, in which:

FIG. 1 is a schematic diagram of a service arrangement for delivery of electrical power and sensing of electric energy usage with a current sensing lug according to the present invention.

FIG. 1A is a schematic diagram of another service arrangement for delivery of electrical power and sensing of electric energy usage with a current sensing lug according to the present invention.

FIG. 2 is an isometric diagram, partially exploded, of portions of the structure of FIG. 1.

FIG. 2A is an isometric diagram, partially exploded, of portions of the structure of FIG. 1A.

FIG. 3 is an enlarged isometric view taken partly in cross section, of the current sensing lug of FIGS. 1 and 1A.

To better understand the invention, we shall carry out the detailed description of some of the modalities of the same, shown in the drawings with illustrative but not limited purposes, attached to the description herein.

### DETAILED DESCRIPTION

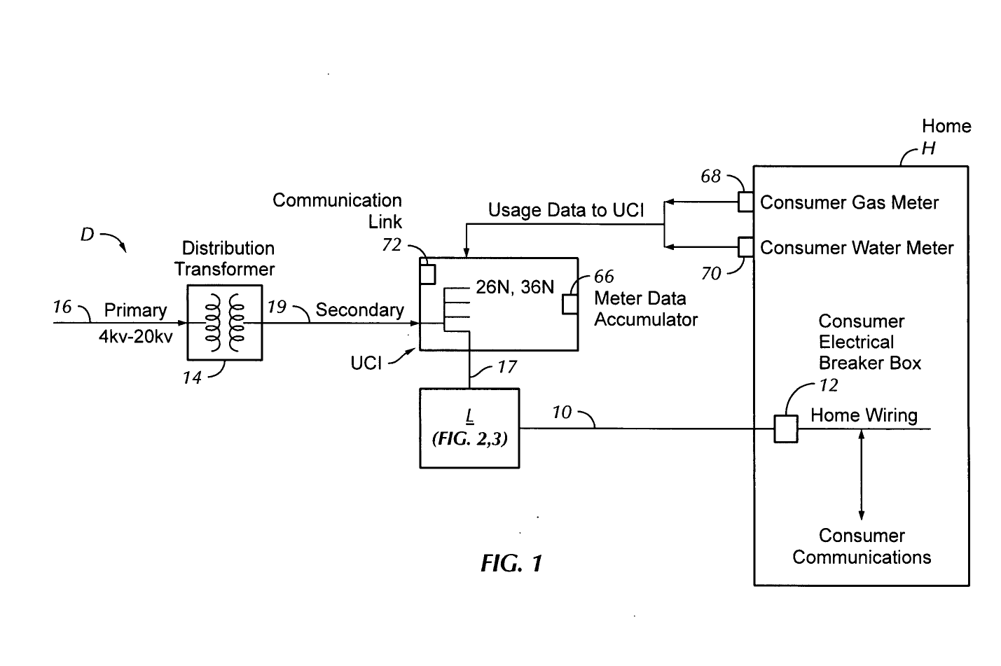

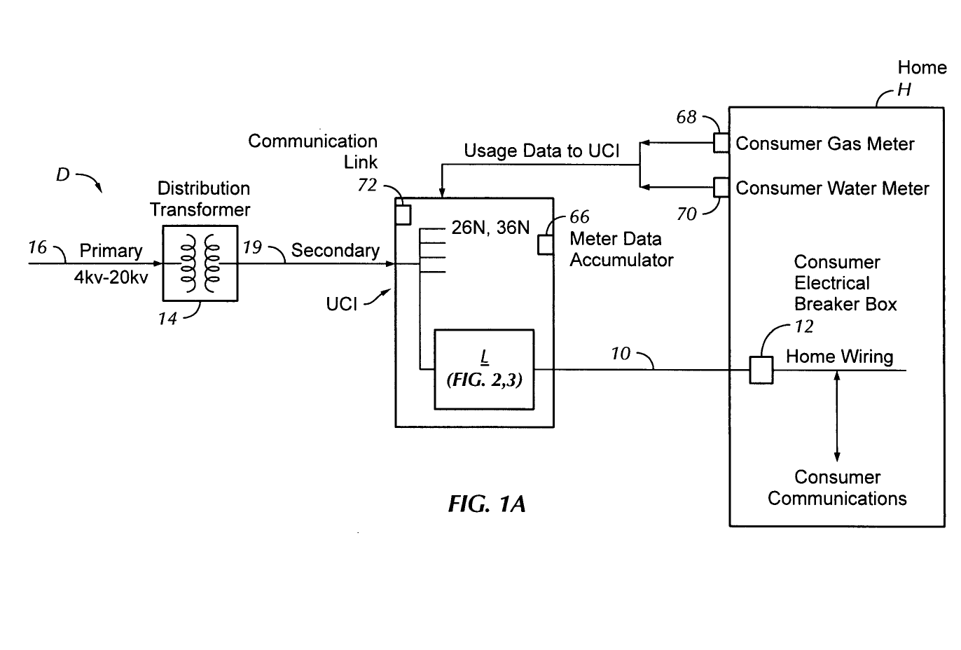

In the drawings, the letter L designates generally a current sensing lug according to the present invention which is provided as a component unit of a power distribution arrangement D (FIGS. 1 and 1A; 2 and 2A) to provide electrical power service to one or more customer sites H. Individual power distribution and connecting lugs L according to the present invention connect individual sites H to the distribution arrangement D and sense the amount of energy used by the site to which they are connected. The example customer site receiving power in FIG. 1 is shown as a home H. It should be understood that the sites connected by lugs L receiving power from the power distribution arrangement D may be buildings, factories, apartments or any other facilities or location receiving electrical power for consumption. Accordingly, the owner or occupants of such sites or other recipients of the electrical power being distributed for energy usage purposes are referred to as customers or users.

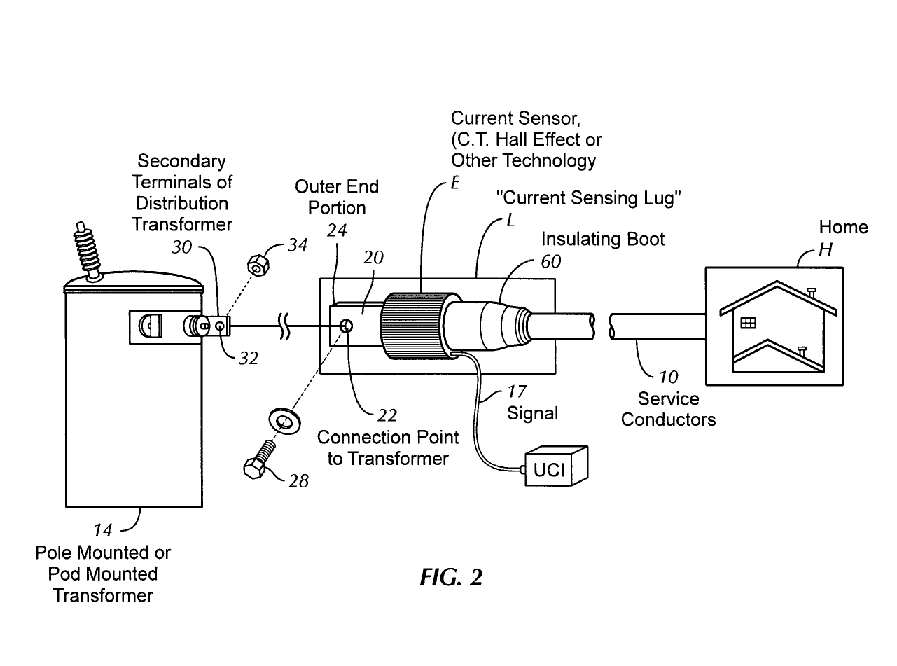

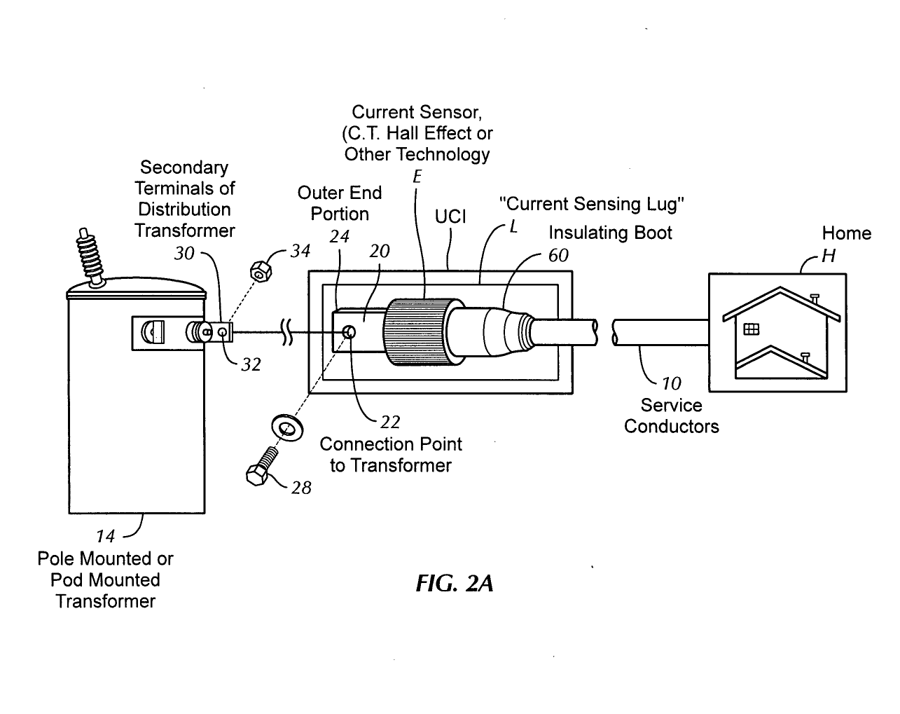

The current sensing lug L is connected to a service conductor 10 which extends between the lug and a customer site H in order to transfer electrical power, typically through a conventional electrical breaker box 12 at the site H. The current sensing lug L is also connected in a manner to be set forth to a distribution transformer 14. The distribution transformer 14 is connected to a primary distribution line 16 of the distribution arrangement D (FIG. 1). In the embodiment of FIGS. 1 and 2, the distribution arrangement D is a pad mounted transformer or pole-mounted transformer arrangement, and the primary distribution line 16 transports power at a primary voltage, for example 7.2 kilovolts or 19.92 kilovolts, to the distribution transformer 14. It should be understood, however, that the distribution transformer 14 may be a pad-mounted transformer and that the lug L of the present invention can be provided for power distribution and sensing with pad-mounted transformers or other power distribution transformers, as well.

The distribution transformer 14 transforms the voltage provided to a customary or typical secondary voltage level, for example 240 volts. The power from the transformer 14 at the customary secondary voltage is transferred at the connection to the lug L to the service conductor 10. As will be set forth the lug L of the present invention senses the amount of current furnished over the service conductor 10 to the associated customer site H with which that lug L is connected. The lug L also provides data about the amount of energy for billing, energy usage monitoring and other purposes. Depending on the number of customer sites H and the distribution capacity of the transformer 14, one or several lugs L according to the present invention may be connected for providing power, each to a separate customer site H.

In the embodiments shown, the current sensing lug L is connected to furnish data to a usage and data collection unit UCI of the type described and disclosed in commonly owned, co-pending U.S. patent application Ser. No. 11/153,304, filed Jun. 15, 2005. As disclosed in that application, the usage and data collection unit UCI obtains electrical energy usage data in electrical power service plus other utility usage data, telemetry and Broadband services which are provided to one or more consumers as shown schematically. The unit UCI in FIG. 1 is shown schematically for an overhead or underground power distribution arrangement. As is shown schematically in FIG. 2, the unit UCI may be directly connected to the distribution transformer 14, if desired. In FIG. 1A, the current sensing lug L is contained as a component within the unit UCI, as shown.

When the unit UCI of the present invention is located as shown in FIGS. 1 and 2, it is connected as shown schematically by a signal 17 to the lug L. The signal 17 may be provided by a wired signal transfer conductor of suitable data transmission capacity physically connecting the lug L and the unit UCI. Alternatively, the signal 17 may be transmitted through wireless signal transfer by electromagnetic wave of a suitable frequency and data transmission bandwidth for data transfer purposes. The unit UCI serves to integrate the data collection and reporting of utility usage data from electric and other utilities as well as facilitates the injection of such data as well as other telemetry or Broadband signals onto the service conductors from multiple Broadband services and thus is referred to as a utilities communication integrator (UCI).

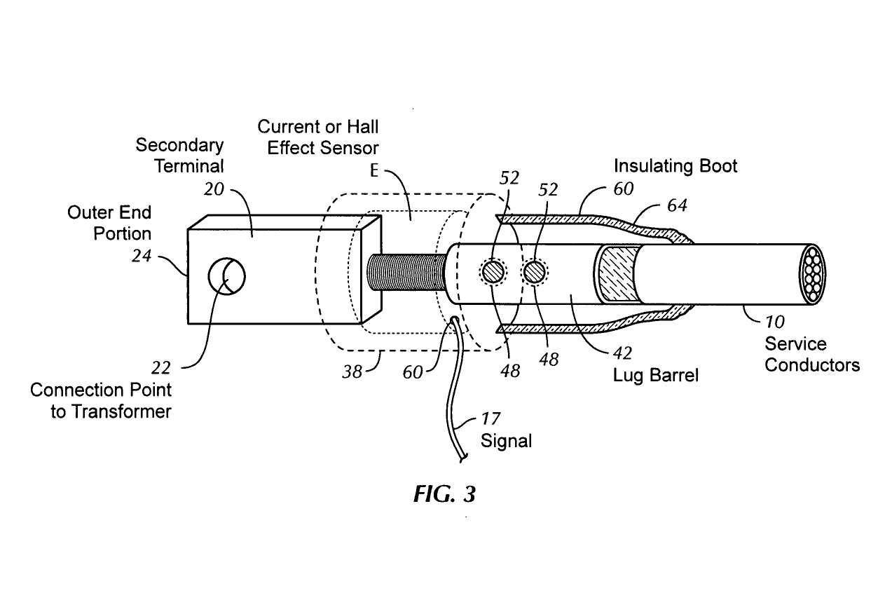

The current sensing lug L may also be provided as a component within the unit UCI as shown in FIGS. 1A and 2A. In such situations a separate current sensing lug L is provided for each customer site or sites H over the service conductor 10 associated with that site. The unit UCI of the type shown in FIGS. 1A and 2A containing the current sensing lug L as a component may be mounted so that it is directly connected to the distribution transformer 14. The unit UCI shown in FIGS. 1A and 2A may also be located on or with the same support structure, such as a pole mounting, a pad mounting or other support for the distribution transformer 14. In each of the foregoing situations, the location of the unit UCI and the lug L is to be considered as in proximity to the distribution transformer 14. The unit UCI shown in FIGS. 1A and 2A may also be located so that it is at a location separate and apart from the transformer 14 and connected by a secondary conductor or bus 19 between the transformer 14 and the unit UCI. The sensing lug L in FIGS. 2, 2A and 3 is otherwise of like construction and operation in either such case.

Current sensing lug L is provided with an electrical current sensor E (FIGS. 2 and 2A) which obtains data readings indicating the amount of energy provided to the customer site or sites H over the respective service conductor 10 associated with such site or sites. For overhead transformer application, the lug L includes a conductive secondary terminal 20 of suitable current carrying capability and formed of a material of required conductivity, such as copper, aluminum or some suitable alloy thereof. It should be understood that other forms of terminals than shown in FIGS. 2 and 2A, such as a spade terminal or a threaded terminal may be used as well.

A connector point 22 is formed in an outer end portion 24 of the terminal 20 for receipt of a connector bolt 28 (FIG. 2) or other conventional connector or fastener devices so that the terminal 20 may be connected to a secondary terminal 30 on the distribution transformer 14. In situations where the terminal 20 has more than one connector point, a corresponding number of bolts or other connectors or fasteners may be used. The terminal 20 has an eyelet or port 32 which is aligned with the eyelet 22 of terminal 20 for connecting the lug L to the distribution transformer 14. When the eyelets 22 and 32 are aligned, the connector bolt 28 is inserted and a fastener nut 34 is applied to make the connection for power transfer from the transformer 14 to the lug L. The distribution transformer 14, as shown in FIG. 2, may have other types of secondary terminals, such as those used in pad mounted transformers, for connection to other lugs L for power distribution and sensing for other consumer or user sites.

The sensor housing is preferably either encapsulated or moisture-resistant to protect the electronic components and connections therein. A lug barrel 42 (FIG. 3) has an elongated opening to receive an end portion of service conductor 10, extending outwardly from an insulative wall. A suitable number of openings 48 are formed in a side wall 50 of the lug barrel 42 to receive set screws 52. The set screws 52 are tightened down onto the end portion of the service conductor 10 once the end portion is fitted into the lug barrel 42.

The electrical current sensor E of the present invention preferably takes the form of a current flow sensor arranged to encircle or otherwise be positioned close to the conductive core of lug L. The current sensor E may take the form of a current transformer to indicate sensed current flow through the service conductor, or a Hall effect sensor operating based on the Hall effect to generate a signal proportional to the amount of current flowing to the individual user.

A signal as indicated schematically at 17 conveys readings to the unit UCI to indicate at times of interest the amount of current sensed as flowing into the various service conductors 10 which have current sensors E associated therewith. The amount of current flowing over time to a particular user or customer, combined with the voltage level at which the current is provided, is an accurate indication of power consumed, since the voltage level may be measured by a voltage device in the unit UCI. It should be understood that other types of current flow sensors or transducers may also be used to sense electrical power furnished to the users and consumers.

The connection between the service conductor 10 and the power connection lug L is covered within a conventional insulating boot 60 of rubber or other comparable material such as a suitable insulative elastomer.

When the lug L is thus installed and connected between the required service conductor 10 and the distribution transformer 14, readings from the individual electrical current sensors E are furnished to a meter data accumulator 66 (FIGS. 1 and 1A) which stores the electrical energy usage data provided to the user/consumer from the distribution transformer 14. The electrical current sensor E of the lug L provides electrical usage data to the meter data accumulator in the unit UCI in the manner disclosed in applicant's commonly owned, co-pending U.S. Patent Application previously referenced.

The unit UCI is preferably of the type according to the previously mentioned co-pending commonly owned U.S. Patent Application and is thus also adapted to gather utility data for gas and water utility services from meters 68 and 70, in addition to electrical energy usage with current sensors E. The current sensor E for each individual consumer/user creates signals, which are provided as current flow readings and thus electrical energy readings for storage in an accumulator memory or storage register of the data accumulator in the unit UCI. The storage register accumulates readings of energy usage versus elapsed time and forms an indication of such usage. In the data accumulator memory of the unit UCI, a user identifier code or prefix unique to the user or consumer being served is also added or included as an identifier to the usage data.

The integrated metering data may be sent by way of a communications link 72, as disclosed in the commonly owned, co-pending application previously referenced. The data from the unit UCI may be sent using a variety of telecommunication technology media, such as: wire; coaxial cable; fiber optic cable or other cable media; BPL or broad band powerline carrier; PLC or power line carrier; WIFI (Wireless Fidelity); and the like. Wireless communications may also be used.

When power line carrier communication of certain types are used, BPL/PLC converters/injectors (hop-on connectors) are provided to transfer the meter usage data and other signals to the electrical utility conductors. The telecommunications technology provided for data readings transmission also makes available interactive communication, typically between, the consumer, and the utilities through the unit UCI. Finally, the unit UCI serves through the telecommunications technology of the foregoing types as the point of communication for the consumer's Broadband services such as CATV, telephone or ISP.

From the foregoing, it can be seen that the present invention is adapted for use in connection with a variety of power applications and with a variety of arrangements for furnishing electrical power to a consumer or user's facility.

The current sensing lug L of the present invention is used in connection with underground residential power distribution arrangement, or it may be a pole mounted unit in connection with overhead electrical power distribution arrangements. The current sensing lug L is preferably connected to the usage and data collection unit UCI, as previously discussed to obtain utility usage data. However, it is to be noted that there is no meter that needs to be read for any user. Rather, the unit UCI transmits the data readings to a data collection facility as used for individual users for billing purposes and there is no need for conventional meter readings to take place.

The invention has been sufficiently described so that a person with average knowledge in the matter may reproduce and obtain the results mentioned in the invention herein. Nonetheless, any skilled person in the field of technique, subject of the invention herein, may carry out modifications not described in the request herein, to apply these modifications to a determined structure, or in the manufacturing process of the same, requires the claimed matter in the following claims; such structures shall be covered within the scope of the invention.

It should be noted and understood that there can be improvements and modifications made of the present invention described in detail above without departing from the spirit or scope of the invention as set forth in the accompanying claims.

That which is claimed is:

1. A current sensing lug connecting electrical power service from a power distribution system to a customer site and measuring energy usage by the customer site, comprising:
a connector terminal adapted to be connected to the power distribution system;
a connector barrel adapted to be connected to a service conductor in connection with the customer site;
a lug body mounted between the connector terminal and the connector barrel and permitting the flow of electrical power to the service conductor; and
an electrical current sensor obtaining data indicating the amount of power provided from the connector terminal to the service conductor.

2. The current sensing lug of claim 1, further including:
a cover enclosing the connection between the service conductor and the current sensing lug.

3. The current sensing lug of claim 2, wherein the cover comprises an insulating boot.

4. The current sensing lug of claim 1, wherein:
the electrical current sensor is mounted about the lug body.

5. The current sensing lug of claim 1, wherein the electrical power service is by underground distribution through a secondary distribution transformer connected to the connector terminal.

6. The current sensing lug of claim 1, where in the electrical power service is by overhead distribution through a secondary distribution transformer connected to the connector terminal.

7. The current sensing lug of claim 1, wherein the current sensor comprises a current flow sensor measuring the flow of electrical current to the service conductor.

8. The current sensing lug of claim 7, wherein the current flow sensor comprises a Hall effect current sensor.

9. The current sensing lug of claim 7, wherein the current flow sensor comprises a current transformer.

10. The current sensing lug of claim 1, further including a signal transfer means for providing data from the current sensor for processing.

11. The current sensing lug of claim 10, wherein the signal transfer means comprises a wireless signal transfer means.

12. The current sensing lug of claim 10, wherein the signal transfer means comprises a wired signal transfer means.

13. The current sensing lug of claim 1, wherein the connector terminal is connected to receive electrical power from a secondary voltage line of a power distribution system.

14. The current sensing lug of claim 1, wherein the connector terminal is connected to a power distribution transformer.

15. The current sensing lug of claim 1, wherein the power distribution transformer is connected to an underground residential power distribution system.

16. The current sensing lug of claim 1, wherein the power distribution transformer is connected to an overhead distribution system.

17. The current sensing lug of claim 1, wherein the connector terminal is connected to receive electrical power from a step transformer.

18. The current sensing lug of claim 1, wherein a service conductor is connected between the connector barrel end portions and a customer site.
